(19) United States
(12) Patent Application Publication
(10) Pub. No.: US 2024/0105492 A1
(43) Pub. Date: Mar. 28, 2024

(54) THERMAL PROCESSING APPARATUS, OPERATION METHOD THEREOF, AND PHOTO SPINNER EQUIPMENT HAVING BAKE UNIT AS THE THERMAL PROCESSING APPARATUS

(71) Applicant: SEMES CO., LTD., Cheonan-si (KR)

(72) Inventors: Jong Gun LEE, Cheonan-si (KR); Jin Taek OH, Cheonan-si (KR)

(73) Assignee: SEMES CO., LTD., Cheonan-si (KR)

(21) Appl. No.: 18/241,887

(22) Filed: Sep. 3, 2023

(30) Foreign Application Priority Data
Sep. 27, 2022 (KR) 10-2022-0122604

(51) Int. Cl. H01L 21/683; G03F 7/40; H01L 21/324; H01L 21/67; H01L 21/687

(52) U.S. Cl. CPC H01L 21/6838; G03F 7/40; H01L 21/324; H01L 21/67109; H01L 21/6875

(57) ABSTRACT

Proposed is a thermal processing apparatus, an operation method thereof, and photo spinner equipment having a bake unit as the thermal processing apparatus, capable of uniformly applying heat to the entire area of a substrate by minimizing defamation of the substrate using low vacuum pressure. The thermal processing apparatus includes the base plate provided in a disc shape, a support pin provided on an upper surface of the base plate, a vacuum hole formed through the base plate, and a protruding member provided at a height lower than that of the support pin on the upper surface of the base plate.

### CROSS REFERENCE TO RELATED APPLICATION

The present application claims priority to Korean Patent Application No. 10-2022-0122604, filed Sep. 27, 2022, the entire contents of which is incorporated herein for all purposes by this reference.

### BACKGROUND OF THE INVENTION

### Field of the Invention

The present disclosure relates to a thermal processing apparatus that performs a thermal process on a substrate, an operation method thereof, and photo spinner equipment having a bake unit as the thermal processing apparatus.

### Description of the Related Art

Semiconductor fabrication is a process of manufacturing a final product by performing tens to hundreds of process steps on a substrate (wafer), and for each step, specialized equipment is used to perform a corresponding step. During semiconductor manufacturing, coating for forming a liquid film on a substrate is performed prior to lithography for creating a pattern on the substrate.

After the liquid film is formed on the substrate and exposed, a thermal process (or baking) of applying thermal energy to the substrate is performed. In the thermal process, thermal energy is applied to the substrate from below the substrate. At this time, it is important to uniformly apply thermal energy to the entire area of the substrate. However, during the manufacturing processes, warpage in which a substrate is twisted, bent, or warped occurs, and due to the twisting or bending of the substrate, the thermal energy applied to the substrate from a heat source thereunder varies for each area of the substrate, which is problematic.

Korean Patent No. 10-1914483 proposes a method of adsorbing a substrate to a support plate by applying vacuum pressure through a vacuum hole in order to uniformly apply heat to the bent substrate.

The problem is that a large vacuum pressure is required for adhesion of the substrate. When a large vacuum pressure is applied, the deformation of the substrate increases according to the degree of warpage of the substrate, which adversely affects the temperature distribution.

### DOCUMENTS OF RELATED ART

(Patent Document 0001) Korean Patent No. 10-0467916
(Patent Document 0002) Korean Patent Application Publication No. 10-2001-0076522
(Patent Document 0003) Korean Patent No. 10-1914483
(Patent Document 0004) Korean Patent No. 10-2385650

### SUMMARY OF THE INVENTION

Accordingly, the present disclosure has been made keeping in mind the above problems occurring in the related art, and the present disclosure is intended to provide a thermal processing apparatus, an operation method thereof, and photo spinner equipment having a bake unit as the thermal processing apparatus, capable of uniformly applying heat to the entire area of a substrate by minimizing deformation of the substrate using low vacuum pressure.

In order to achieve the above objective, according to an embodiment of the present disclosure, there is provided a thermal processing apparatus that performs a thermal process on a substrate. The apparatus includes: a base plate provided in a disc shape; a support pin provided on an upper surface of the base plate; a vacuum hole foamed through the base plate; and a protruding member provided at a height lower than that of the support pin on the upper surface of the base plate.

According to the embodiment of the present disclosure, heat may be applied to the substrate through a hot wire provided on a lower surface of the base plate.

According to the embodiment of the present disclosure, the support pin, the vacuum hole, and the protruding member may be positioned adjacent to each other.

According to the embodiment of the present disclosure, the protruding member may be provided in a wall shape along a circumferential direction from a center of the base plate.

According to the embodiment of the present disclosure, the protruding member may include: an inner protruding member provided in a wall shape along the circumferential direction from the center of the base plate; and an outer protruding member provided in a wall shape along the circumferential direction from the outside of the inner protruding member with respect to the center of the base plate.

According to the embodiment of the present disclosure, the support pin may include: inner support pins arranged along a periphery of the inner protruding member; and outer support pins arranged along a periphery of the outer protruding member.

According to the embodiment of the present disclosure, the vacuum hole may include: inner vacuum holes arranged along a periphery of the inner protruding member; and outer vacuum holes arranged along a periphery of the outside protruding member.

According to the embodiment of the present disclosure, outer vacuum holes may be formed along the circumferential direction on the outside of the outer protruding member, and outer support pins may be formed along the circumferential direction on the inside of the outer protruding member.

According to the embodiment of the present disclosure, inner support pins may be famed along the circumferential direction on the outside of the inner protruding member, and inner vacuum holes may be formed along the circumferential direction on the outside of the inner support pins.

An operation method of the thermal processing apparatus according to the present disclosure includes: placing the substrate on the support pin; applying a first vacuum pressure to the vacuum hole to bring the substrate into close contact with the base plate; performing a thermal process on the substrate by supplying power to a hot wire provided on the base plate; and applying a second vacuum pressure to the vacuum hole while the thermal process is being performed.

According to the embodiment of the present disclosure, the second vacuum pressure may be set to be greater than the first vacuum pressure.

Photo spinner equipment according to the present disclosure includes: an index module configured to transport a substrate from a container in which the substrate is stored; a treating module configured to perform a coating process and a developing process on the substrate and include a bake unit that performs a thermal process on the substrate; and an interface module configured to connect the treating module with external exposure equipment. The bake unit may include: a base plate provided in a disc shape; a support pin provided on an upper surface of the base plate; a vacuum hole formed through the base plate; and a protruding member provided at a height lower than that of the support pin on the upper surface of the base plate. A first vacuum pressure may be applied to the vacuum hole to bring the substrate into close contact with the base plate, and the second vacuum pressure lower than the first vacuum pressure may be applied to the vacuum hole while the substrate is subjected to a thermal process.

According to the present disclosure, since the resistance of air flow is increased by means of protruding members provided on the upper surface of a base plate, a substrate can be brought into close contact with the base plate even when by a low vacuum pressure, thereby minimizing deformation of the substrate. Therefore, since the substrate is adsorbed using a low vacuum pressure, the substrate is less deformed and heat can be uniformly applied to the entire area of the substrate.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 schematically shows the appearance of photo spinner equipment to which the present disclosure may be applied;

FIG. 2 shows a schematic layout of the photo spinner equipment;

FIG. 3 shows a coating block of the photo spinner equipment;

FIG. 4 schematically shows a thermal processing apparatus viewed from above;

FIG. 5 is a cross-sectional view of the line A-B in the thermal processing apparatus shown in FIG. 4;

FIG. 6 is a view showing air flow in the cross-sectional view of the thermal processing apparatus of FIG. 5; and

FIG. 7 is a flowchart showing an operation method of the thermal processing apparatus according to the present disclosure.

### DETAILED DESCRIPTION OF THE INVENTION

Hereinafter, with reference to the accompanying drawings, embodiments of the present disclosure will be described in detail so that those skilled in the art may easily carry out the present disclosure. The present disclosure may be embodied in many different forms and is not limited to the embodiments set forth herein.

In order to clearly describe the present disclosure, parts irrelevant to the description are omitted, and the same reference numerals are assigned to the same or similar components throughout the specification.

In addition, in various embodiments, components having the same configuration will be described only in representative embodiments by using the same reference numerals, and in other embodiments, only configurations different from the representative embodiments will be described.

Throughout the specification, when a part is said to be “connected (or coupled)” to another part, this includes not only the case of being “directly connected (or coupled)” but also “indirectly connected (or coupled)” with another member in between. In addition, when a part “includes”, “has”, or “comprises” a certain part, this means that other components may be further included without excluding other components unless otherwise stated.

Unless otherwise defined, all terms used herein, including technical or scientific terms, have the same meaning as commonly understood by a person skilled in the art. Terms such as those defined in the commonly used dictionaries should be construed as having meanings consistent with the meanings in the context of the related art and shall not be construed in ideal or excessively formal meanings unless expressly defined in this application.

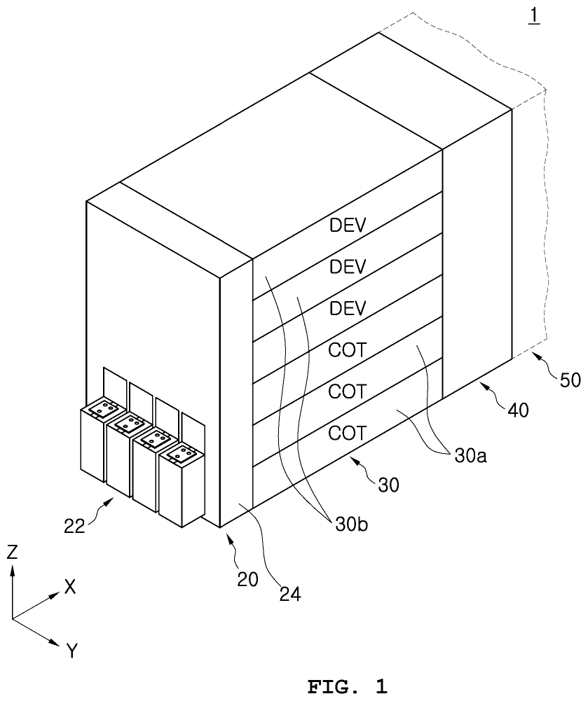

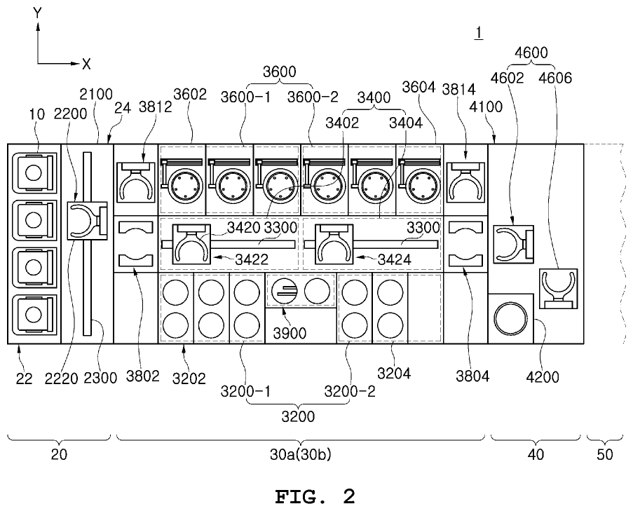

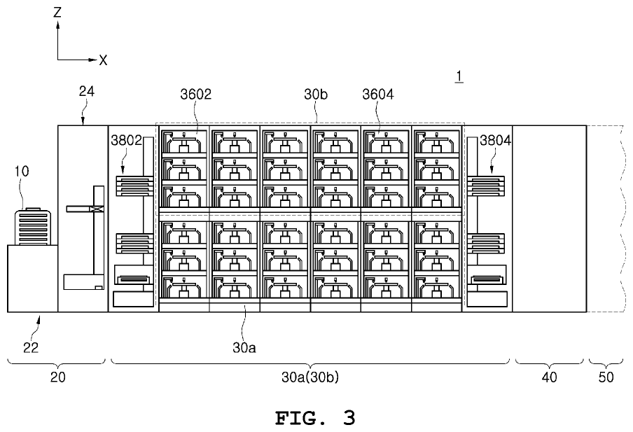

FIG. 1 schematically shows the appearance of photo spinner equipment 1 to which the present disclosure may be applied; FIG. 2 shows a schematic layout of the photo spinner equipment 1; and FIG. 3 shows a coating block 30a of the photo spinner equipment 1.

Referring to FIGS. 1 to 3, the photo spinner equipment 1 includes: an index module 20 that transports a substrate W from a container 10 in which the substrate W is stored; a treating module 30 that performs a coating process and a developing process on the substrate W and includes a bake unit 3200 performing a thermal process on the substrate W; and an interface module 40 that connects the treating module 30 with external exposure equipment 50.

The index module 20, the treating module 30, and the interface module 40 may be sequentially arranged in a line. Hereinafter, the direction in which the index module 20, the treating module 30, and the interface module 40 are arranged is defined as a first horizontal direction X, the direction perpendicular to the first horizontal direction X is defined as a second horizontal direction Y when viewed from above, and the direction perpendicular to both the first horizontal direction X and the second horizontal direction Y is defined as a vertical direction Z.

The index module 20 transports a substrate W from the container 10 in which the substrate W is stored to the treating module 30, and stores the treated substrate W into the container 10. The longitudinal direction of the index module 20 is provided as the second horizontal direction Y. The index module 20 has a load port 22 and an index frame 24. Based on the index frame 24, the load port 22 is located on the opposite side of the treating module 30. The container 10 in which the substrates W are stored is placed in the load port 22. A plurality of load ports 22 may be provided, and the plurality of load ports 22 may be arranged in a line along the second horizontal direction Y.

As the container 10, an airtight container such as a front opening unified pod (FOUP) may be used. The container 10 may be placed in the load port 22 by a transport means (not shown) such as an overhead transfer, overhead conveyor, or automatic guided vehicle or by an operator.

An index robot 2200 is provided inside the index frame 24. A guide rail 2300 with its longitudinal direction along the second horizontal direction Y is provided inside the index frame 24, and the index robot 2200 may be provided to be movable on the guide rail 2300. The index robot 2200 may include a hand 2220 on which the substrate W is placed, and the hand 2220 may move forward and backward, rotate about the vertical direction Z as an axis, and move along the vertical direction Z.

The treating module 30 performs a coating process and a developing process on the substrate W.

The treating module has a coating block 30a and a developing block 30b. The coating block 30a performs a coating process on the substrate W, and the developing block 30b performs a developing process on the substrate W. A plurality of coating blocks 30a are provided, and the coating blocks 30a are provided stacked on top of each other. A plurality of developing blocks 30b are provided, and the developing blocks 30b are provided stacked on top of each other.

According to the embodiment of FIG. 1, three coating blocks 30a are provided, and three developing blocks 30b are provided. The coating blocks 30a may be disposed below the developing blocks 30b.

As an example, the plurality of coating blocks 30a may perform the same process and be provided with the same structure. In addition, the plurality of developing blocks 30b may perform the same process and be provided with the same structure. However, the arrangement and configuration of the coating block 30a and the developing block 30b in the photo spinner equipment 1 to which the present disclosure may be applied is not limited to the structure shown in FIG. 1, and various changes may be applied.

Referring to FIG. 2, the coating block 30a includes: a bake unit 3200, a transport part 3400, and a liquid treating part 3600.

The transport part 3400 transports the substrates W between the bake unit 3200 and the liquid treating part 3600 within the coating block 30a. The transport part 3400 may include a first transport section 3402 as a first movement passage and a second transport section 3404 as a second movement passage. The first and second transport sections 3402 and 3404 are provided in a longitudinal direction parallel to the first horizontal direction X and connected to each other. First and second transport robots 3422 and 3424 are provided in the first and second transport sections 3402 and 3404, respectively.

As an example, the first and second transport robots 3422 and 3424 have a robot hand 3420 on which the substrate W is placed, and the robot hand 3420 may move forward and backward, rotate about the vertical direction Z as an axis, and move along the vertical direction Z. A guide rail 3300 whose longitudinal direction is parallel to the first horizontal direction X is provided in each of the first and second transport sections 3402 and 3404, and the transport robots 3422 and 3424 may be movable on the guide rail 3300.

Referring to FIG. 2, the first and second transport sections 3402 and 3404 may be provided with the same structure. The first transport section 3402 is located closer to the index module 20, and the second transport section 3404 is located closer to the interface module 40.

The bake unit 3200 performs a thermal process on the substrate W. The bake unit 3200 corresponds to an example of a thermal processing apparatus 100 to be described later. The thermal process may include a cooling process and a heating process. The liquid treating part 3600 supplies liquid to the substrate W to form a liquid film. The liquid film may be a photoresist film or an anti-reflection film.

The liquid treating part 3600 may include: a first liquid treating part 3600-1 having liquid treating chambers for applying an anti-reflection film to a substrate; and a second liquid treating part 3600-2 having liquid treating chambers for applying a photoresist film to a substrate coated with an anti-reflection film. The first liquid treating part 3600-1 is disposed on one side of the first transport section 3402 while the second liquid treating part 3600-2 is disposed on one side of the second transport section 3404.

The liquid treating part 3600 has a plurality of liquid treating chambers 3602 and 3604. The plurality of liquid treating chambers 3602 and 3604 may be disposed along the longitudinal direction of the transport part 3400. In addition, some of the liquid treating chambers 3602 and 3604 may be provided to be stacked on top of each other.

The bake unit 3200 may include: a first bake unit 3200-1 having thermal processing chambers 3202 for thermal processing of a substrate in connection with the application of the anti-reflection film; and a second bake unit 3200-2 having thermal processing chambers 3204 for thermal processing of a substrate in connection with the application of the photoresist film. The first bake unit 3200-1 is disposed on one side of the first transport section 3402, while the second bake unit 3200-2 is disposed on one side of the second transport section 3404. The thermal processing chambers 3202 disposed on the side of the first transport section 3402 are referred to as front thermal processing chambers, and the thermal processing chambers 3204 disposed on the side of the second transport section 3404 are referred to as rear thermal processing chambers.

That is, the first liquid treating part 3600-1 and the first bake unit 3200-1 for forming an anti-reflection film on a substrate are disposed in the first transport section 3402, while the second liquid treating part 3600-2 and the second bake unit 3200-2 for forming a photoresist film on a substrate are disposed in the second transport section 3404.

Meanwhile, the treating module 30 includes a plurality of buffer chambers 3802 and 3804. Some of the buffer chambers 3802 among the plurality of buffer chambers 3802 and 3804 are disposed between the index module 20 and the transport part 3400. The buffer chamber 3802 may be referred to as a front buffer. The plurality of buffer chambers 3802 are provided and positioned to be stacked on top of each other in the vertical direction Z. Some other buffer chambers 3804 among the plurality of buffer chambers 3802 and 3804 are disposed between the transport part 3400 and the interface module 40. The buffer chamber 3804 may be referred to as a rear buffer. The plurality of buffer chambers 3804 are provided and positioned to be stacked on top of each other in the vertical direction Z. The buffer chambers 3802 and 3804 temporarily store the substrates W. Meanwhile, buffer transport robots 3812 and 3814 for transporting substrates may be provided in the buffer chambers 3802 and 3804.

An interface buffer 4100 provides a space where the substrates W transported between the coating block 30a, an additional process chamber 4200, an exposure equipment 50, and the developing block 30b temporarily stays during transport. A plurality of interface buffers 4100 are provided, and the plurality of interface buffers 4100 may be stacked on top of each other.

A transport member 4600 transports the substrates W between the coating block 30a, the additional process chamber 4200, the exposure equipment 50, and the developing block 30b. The transport member 4600 may be provided as one or a plurality of robots. As an example, the transport member 4600 may include a first interface robot 4602 and a second interface robot 4606.

The first interface robot 4602 may transport the substrates W between the coating block 30a, the additional process chamber 4200, and the interface buffer 4100, while the second interface robot 4606 may transport the substrates W between the interface buffer 4100 and the exposure equipment 50.

Hands of the index robot 2200, the first interface robot 4602, and the second interface robot 4606 may all be provided in the same shape as the robot hands 3420 of the transport robots 3422 and 3424. Alternatively, the hand of the robot that directly transports the substrate W to and from a transport plate 3240 of the thermal processing chamber may be provided in the same shape as the robot hands 3420 of the transport robots 3422 and 3424, and the hands of the other robots may be provided in a different shape.

Referring to FIG. 2, a cooling transport module 3900 is provided for transporting substrates between the first transport robot 3422 and the second transport robot 3424, and for substrate cooling. The cooling transport module 3900 is disposed in the bake unit 3200 adjacent to the boundary where the first movement path of the first transport robot 3422 and the second movement path of the second transport robot 3424 come into contact with each other. The cooling transport module 3900 may be stacked in multiple stages like the thermal processing chambers.

Hereinafter, the thermal processing apparatus 100 according to the present disclosure will be described. The thermal processing apparatus 100 of the present disclosure may correspond to the bake unit 3200 of the photo spinner equipment 1.

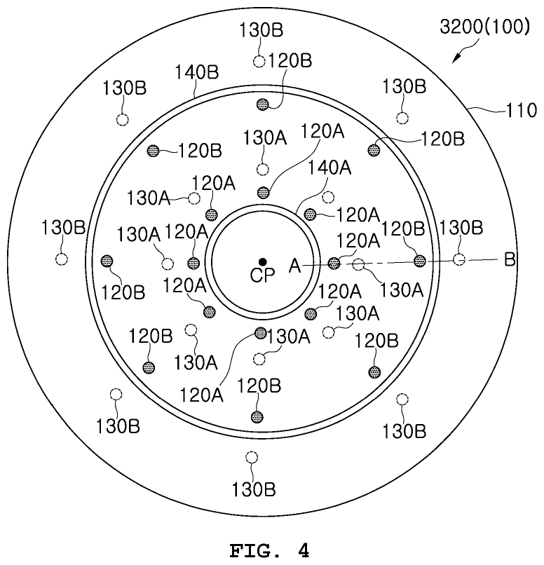

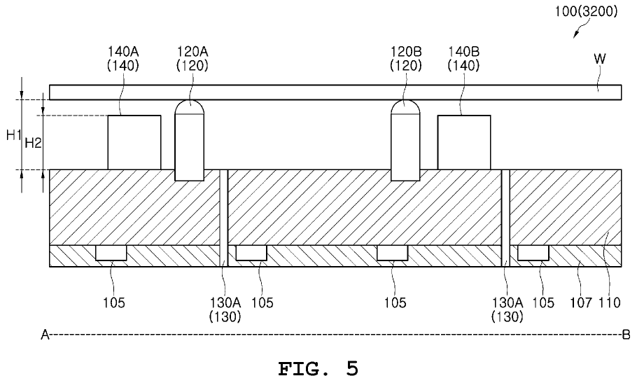

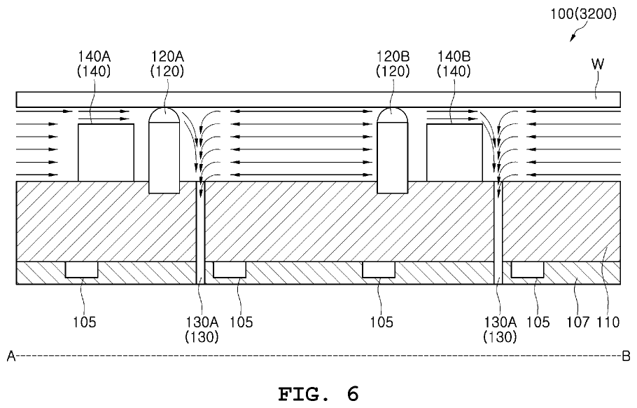

FIG. 4 schematically shows the thermal processing apparatus 100 viewed from above; FIG. 5 is a cross-sectional view of the line A-B in the thermal processing apparatus 100 shown in FIG. 4; and FIG. 6 is a view showing air flow in the cross-sectional view of the thermal processing apparatus 100 of FIG. 5.

The thermal processing apparatus 100 for performing a thermal process on a substrate W according to the present disclosure includes: a base plate 110 provided in a disc shape; a support pin 120 provided on the upper surface of the base plate 110; a vacuum hole 130 formed through the base plate 110; and a protruding member 140 provided at a height lower than that of the support pin 120 on the upper surface of the base plate 110.

According to the present disclosure, when a substrate W is seated on the support pin 120, vacuum pressure is applied through the vacuum hole 130 so that the substrate W is brought into close contact with the support pin 120 toward the base plate 110. At this time, since the space between the substrate W and the protruding member 140 is narrowed due to the vacuum pressure applied to the vacuum hole 130, the resistance of air flow increases and a relatively large air pressure is formed, so that even when a low vacuum pressure is applied to the vacuum hole 130, the substrate W may be brought into close contact with the base plate. Thereafter, thermal energy is transferred from a hot wire 105 to the substrate W. At this time, since low vacuum pressure is used to immobilize the substrate W, the deformation of the substrate is small, and thus heat may be uniformly applied to the entire area of the substrate.

The base plate 110 has a disc shape corresponding to the substrate W, and may be made of an aluminum nitride (AlN) material. Referring to FIG. 5, the support pin 120 for supporting the substrate W and the protruding member 140 for controlling airflow are provided on the upper surface of the base plate 110. The hot wire 105 may be attached to the lower surface of the base plate 110 while being buried by a coating layer 107. Heat may be applied to the substrate through the hot wire provided on the lower surface of the base plate 110.

Meanwhile, the vacuum hole 130 penetrating the upper and lower surfaces of the base plate 110 is formed. The vacuum hole 130 is connected to a vacuum pump through a pipe, and the vacuum pump applies vacuum pressure to the vacuum hole 130. Accordingly, air flow may be formed in the space between the substrate W and the base plate 110 as shown in FIG. 6.

Referring to FIG. 4, a plurality of support pins 120 and vacuum holes 130 are formed in the circumferential direction from the center CP of the substrate W, and the protruding member 140 may have a circular shape having the same center CP as the substrate W. According to the present disclosure, the protruding member 140 may be formed in a wall shape along the circumferential direction from the center CP of the base plate 110. As shown in FIG. 5, the height H2 of the protruding member 140 is configured lower than the height H1 of the support pin 120, so that a space may be created between the protruding member 140 and the substrate W without the protruding member 140 contacting the substrate W. The protruding member 140 may be made of the same material as the base plate 110. The protruding member 140 may be integrally formed with the base plate 110, or may be attached to or inserted into the upper surface of the base plate 110.

According to the present disclosure, the support pin 120, the vacuum hole 130, and the protruding member 140 may be positioned adjacent to each other. Since the vacuum hole 130 is located around the support pin 120, a stronger airflow is formed around the vacuum hole 130, and the substrate W may be strongly adhered to the support pin 120 by the strong airflow. In addition, since the protruding member 140 is located around the support pin 120 and the vacuum hole 130, the substrate W may adhere more strongly to the support pin 120 due to the high air pressure generated by means of the protruding member 140.

According to the present disclosure, the protruding member 140 includes: an inner protruding member 140A provided in a wall shape along the circumferential direction from the center CP of the base plate 110; and an outer protruding member 140B provided in a wall shape along the circumferential direction from the outside of the inner protruding member 140A with respect to the center CP of the base plate 110. The support pin 120 includes: inner support pins 120A arranged along the periphery of the inner protruding member 140A; and outer support pins 120B arranged along the periphery of the outer protruding member 140B. The vacuum hole 130 includes: inner vacuum holes 130A arranged along the periphery of the inner protruding member 140A; and outer vacuum holes 130B arranged along the periphery of the outer protruding member 140B. In this document, the inward direction refers to a direction toward the center CP of the base plate 110, and the outward direction is the opposite direction to the inward direction and refers to a direction from the center CP of the base plate 110 to the outside.

Referring to FIG. 4, the inner protruding member 140A, the inner support pins 120A, and the inner vacuum holes 130A are provided around the center CP of the base plate 110 along the circumferential direction, while the outer support pins 120B, the outer protruding member 140B, and the outer vacuum holes 130B are provided along the circumferential direction from the outer sides of the inner vacuum holes 130A at the outer portion of the base plate 110.

That is, the outer vacuum holes 130B are formed along the circumferential direction on the outside of the outer protruding member 140B, and the outer support pins 120B are provided along the circumferential direction on the inside of the outer protruding member 140B. In addition, the inner support pins 120A are provided along the circumferential direction on the outside of the inner protruding member 140A, and the inner vacuum holes 130A are formed along the circumferential direction on the outside of the inner support pins 120A.

In other words, the inner support pin 120A and the outer support pin 120B are respectively located on each side of the inner vacuum hole 130A, while the inner protruding member 140A is located inside the inner support pin 120A and the outer protruding member 140B is provided on the outside of the outer support pin 120B. Since strong air pressure is created in the air flow space narrowed by the inner protruding member 140A and the outer protruding member 140B, even when a relatively low vacuum pressure is applied to the vacuum holes 130, the substrate W may be strongly adhered to the inner support pins 120A and the outer support pins 120B located on both sides of the inner vacuum holes 130A.

Meanwhile, the magnitude of the vacuum pressure applied to the vacuum hole 130 may be different depending on the process stage for the substrate W. For example, when the substrate W is initially seated on the support pin 120, a high vacuum pressure (e.g., −10 kpa) may be applied to the vacuum hole 130, and thereafter, when a thermal process is performed on the substrate W, a low vacuum pressure (e.g., −2 kpa) may be applied to the vacuum hole 130. That is, initially, when the substrate W is put in, a relatively high vacuum pressure is applied to induce a strong air flow under the substrate W to generate a traction force for the substrate W in the direction of the base plate 110, and after the substrate W is in close contact with the support pin 120, a relatively low vacuum pressure may be applied to maintain the substrate W in a fixed state.

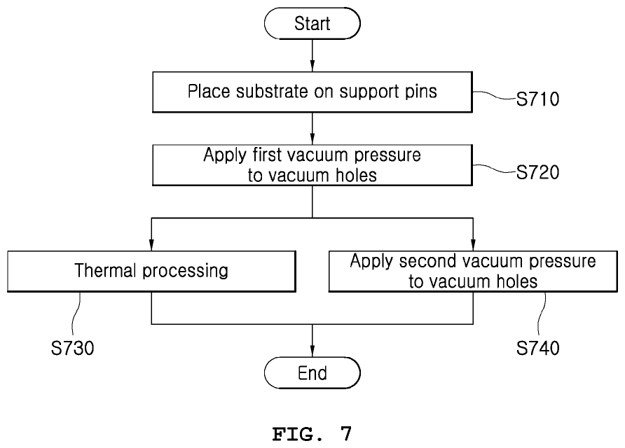

FIG. 7 is a flowchart showing an operation method of the thermal processing apparatus 100 according to the present disclosure. FIG. 7 is a flowchart showing a thermal processing performed by the thermal processing apparatus 100 described with reference to FIGS. 4 to 6. The thermal processing apparatus 100 includes: a base plate 110 provided in a disc shape; a support pin 120 provided on the upper surface of the base plate 110; a vacuum hole 130 formed through the base plate 110; a protruding member 140 provided at a height lower than the support pin 120 on the upper surface of the base plate 110.

The operation method of the thermal processing apparatus 100 according to the present disclosure includes: placing a substrate W on the support pins (S710); applying a first vacuum pressure to the vacuum hole 130 to bring the substrate W into close contact with the base plate 110 (S720); performing a thermal process on the substrate W by supplying power to a hot wire provided on the base plate 110 (S730); and applying a second vacuum pressure to the vacuum hole while the thermal process is being performed (S740).

According to the present disclosure, in the steps of applying the first vacuum pressure (S720) and applying the second vacuum pressure (S740), vacuum pressure is applied through the vacuum hole 130 so that the substrate W is brought into close contact with the support pin 120 toward the base plate 110. At this time, since the space between the substrate W and the protruding member 140 is narrowed due to the vacuum pressure applied to the vacuum hole 130, the resistance of air flow increases and a relatively large air pressure is formed, so that even when a low vacuum pressure is applied to the vacuum hole 130, the substrate W may be brought into close contact with the base plate. In the step of performing a thermal process (S730), thermal energy is transferred to the substrate W. At this time, since low vacuum pressure is used to immobilize the substrate W, the deformation of the substrate is small, and thus heat may be uniformly applied to the entire area of the substrate.

The magnitude of the vacuum pressure applied in the steps of applying the first vacuum pressure (S720) and applying the second vacuum pressure (S740) may be different. The magnitude (absolute value) of the second vacuum pressure may be set to be smaller than the magnitude (absolute value) of the first vacuum pressure. That is, the absolute value of the initially applied first vacuum pressure may be set higher than the absolute value of the second vacuum pressure. For example, when the substrate W is seated on the support pin 120 in the step of applying the first vacuum pressure (S720), a high vacuum pressure (e.g., −10 kpa) may be applied to the vacuum hole 130. Thereafter, in the step of applying the second vacuum pressure (S740), a low vacuum pressure (e.g., −2 kpa) may be applied to the vacuum hole 130. That is, initially, when the substrate W is put in, a relatively high vacuum pressure is applied to induce a strong air flow under the substrate W to generate a traction force for the substrate W in the direction of the base plate 110, and after the substrate W is in close contact with the support pin 120, a relatively low vacuum pressure may be applied to maintain the substrate W in a fixed state.

The thermal processing apparatus 100 and the operation method of the thermal processing apparatus 100 described above may be applied to the bake unit 3200 of the photo spinner equipment 1 described above with reference to FIGS. 1 to 3. The photo spinner equipment 1 according to the present disclosure includes: an index module 20 that transports a substrate W from a container 10 in which the substrate W is stored; a treating module 30 that performs a coating process and a developing process on the substrate W and includes a bake unit 3200 performing a thermal process on the substrate W; and an interface module 40 that connects the treating module 30 with external exposure equipment 50. The bake unit 3200 includes: a base plate 110 provided in a disc shape; a support pin 120 provided on the upper surface of the base plate 110; a vacuum hole 130 formed through the base plate 110; and a protruding member 140 provided at a height lower than that of the support pin 120 on the upper surface of the base plate 110. The first vacuum pressure is applied to the vacuum hole 130 to bring the substrate W into close contact with the base plate 110, and the second vacuum pressure lower than the first vacuum pressure is applied to the vacuum hole 130 while the substrate W is subjected to the thermal process.

According to the present disclosure, heat may be applied to the substrate W through the hot wire 105 provided on the lower surface of the base plate 110.

According to the present disclosure, the support pin 120, the vacuum hole 130, and the protruding member 140 may be positioned adjacent to each other.

According to the present disclosure, the protruding member 140 may be formed in a wall shape along the circumferential direction from the center CP of the base plate 110.

According to the present disclosure, the protruding member 140 may include: an inner protruding member 140A provided in a wall shape along the circumferential direction from the center CP of the base plate 110; and an outer protruding member 140B provided in a wall shape along the circumferential direction from the outside of the inner protruding member 140A with respect to the center CP of the base plate 110.

According to the present disclosure, the support pin 120 may include: inner support pins 120A arranged along the periphery of the inner protruding member 140A; and outer support pins 120B arranged along the periphery of the outer protruding member 140B.

According to the present disclosure, the vacuum hole 130 may include: inner vacuum holes 130A arranged along the periphery of the inner protruding member 140A; and outer vacuum holes 130B arranged along the periphery of the outer protruding member 140B.

According to the present disclosure, the outer vacuum holes 130B may be disposed along the circumferential direction on the outside of the outer protruding member 140B, and the outer support pins 120B may be disposed along the circumferential direction on the inside of the outer protruding member 140B.

According to the present disclosure, the inner support pins 120A may be provided along the circumferential direction on the outside of the inner protruding member 140A, and the inner vacuum holes 130A may be foamed along the circumferential direction on the outside of the inner support pins 120A.

The present embodiments and the drawings accompanying this specification only clearly show some of the technical ideas included in the present disclosure, and it will be apparent that all modifications and specific embodiments that may be easily inferred by those skilled in the art within the scope of the technical idea included in the specification and drawings of the present disclosure are included in the scope of the present disclosure.

Therefore, the spirit of the present disclosure should not be limited to the described embodiments, and it will be said that not only the claims to be described later but also all things that are equivalent to the claims or have equivalent modifications belong to the scope of the present disclosure.

What is claimed is:

1. A thermal processing apparatus that performs a thermal process on a substrate, the apparatus comprising:
a base plate provided in a disc shape;
a support pin provided on an upper surface of the base plate;
a vacuum hole formed through the base plate; and
a protruding member provided at a height lower than that of the support pin on the upper surface of the base plate.

2. The thermal processing apparatus of claim 1, wherein heat is applied to the substrate through a hot wire provided on a lower surface of the base plate.

3. The thermal processing apparatus of claim 1, wherein the support pin, the vacuum hole, and the protruding member are positioned adjacent to each other.

4. The thermal processing apparatus of claim 1, wherein the protruding member is provided in a wall shape along a circumferential direction from a center of the base plate.

5. The thermal processing apparatus of claim 4, wherein the protruding member comprises:
an inner protruding member provided in a wall shape along the circumferential direction from the center of the base plate; and
an outer protruding member provided in a wall shape along the circumferential direction from the outside of the inner protruding member with respect to the center of the base plate.

6. The thermal processing apparatus of claim 5, wherein the support pin comprises:
inner support pins arranged along a periphery of the inner protruding member; and
outer support pins arranged along a periphery of the outer protruding member.

7. The thermal processing apparatus of claim 5, wherein the vacuum hole comprises:
inner vacuum holes arranged along a periphery of the inner protruding member; and
outer vacuum holes arranged along a periphery of the outside protruding member.

8. The thermal processing apparatus of claim 5, wherein outer vacuum holes are formed along the circumferential direction on the outside of the outer protruding member, and outer support pins are formed along the circumferential direction on the inside of the outer protruding member.

9. The thermal processing apparatus of claim 5, wherein inner support pins are formed along the circumferential direction on the outside of the inner protruding member, and inner vacuum holes are formed along the circumferential direction on the outside of the inner support pins.

10. An operation method of a thermal processing apparatus that performs a thermal process on a substrate, wherein the apparatus comprises: a base plate provided in a disc shape; a support pin provided on an upper surface of the base plate; a vacuum hole formed through the base plate; and a protruding member provided at a height lower than that of the support pin on the upper surface of the base plate,
the method comprising:
placing the substrate on the support pin;
applying a first vacuum pressure to the vacuum hole to bring the substrate into close contact with the base plate;
performing a thermal process on the substrate by supplying power to a hot wire provided on the base plate; and
applying a second vacuum pressure to the vacuum hole while the thermal process is being performed.

11. The operation method of a thermal processing apparatus of claim 10, wherein the second vacuum pressure is set to be greater than the first vacuum pressure.

12. Photo spinner equipment, comprising:
an index module configured to transport a substrate from a container in which the substrate is stored;
a treating module configured to perform a coating process and a developing process on the substrate and include a bake unit that performs a thermal process on the substrate; and
an interface module configured to connect the treating module with external exposure equipment,
wherein the bake unit comprises: a base plate provided in a disc shape;
a support pin provided on an upper surface of the base plate;
a vacuum hole formed through the base plate; and
a protruding member provided at a height lower than that of the support pin on the upper surface of the base plate, and
a first vacuum pressure is applied to the vacuum hole to bring the substrate into close contact with the base plate, and a second vacuum pressure lower than the first vacuum pressure is applied to the vacuum hole while the substrate is subjected to a thermal process.

13. The photo spinner equipment of claim 12, wherein heat is applied to the substrate through a hot wire provided on a lower surface of the base plate.

14. The photo spinner equipment of claim 12, wherein the support pin, the vacuum hole, and the protruding member are positioned adjacent to each other.

15. The photo spinner equipment of claim 12, wherein the protruding member is provided in a wall shape along a circumferential direction from a center of the base plate.

16. The photo spinner equipment of claim 15, wherein the protruding member comprises:
an inner protruding member provided in a wall shape along the circumferential direction from the center of the base plate; and
an outer protruding member provided in a wall shape along the circumferential direction from the outside of the inner protruding member with respect to the center of the base plate.

17. The photo spinner equipment of claim 16, wherein the support pin comprises:
inner support pins arranged along a periphery of the inner protruding member; and
outer support pins arranged along a periphery of the outer protruding member.

18. The photo spinner equipment of claim 16, wherein the vacuum hole comprises:
inner vacuum holes arranged along a periphery of the inner protruding member; and
outer vacuum holes arranged along a periphery of the outside protruding member.

19. The photo spinner equipment of claim 16, wherein outer vacuum holes are formed along the circumferential direction on the outside of the outer protruding member, and outer support pins are formed along the circumferential direction on the inside of the outer protruding member.

20. The photo spinner equipment of claim 16, wherein inner support pins are formed along the circumferential direction on the outside of the inner protruding member, and inner vacuum holes are formed along the circumferential direction on the outside of the inner support pins.
